(19) United States
(12) Patent Application Publication
(10) Pub. No.: US 2020/0214155 A1
(43) Pub. Date: Jul. 2, 2020

(54) ELECTRONIC DEVICE WITH CAPABILITY OF COVERING AN IMAGE CAPTURING MODULE THEREOF

(71) Applicant: IEI Integration Corp., New Taipei City (TW)

(72) Inventors: Yu-Tsung Chang, New Taipei City (TW); Yu-Hsuan Liao, New Taipei City (TW)

(21) Appl. No.: 16/391,315

(22) Filed: Apr. 23, 2019

(30) Foreign Application Priority Data
Jan. 2, 2019 (TW) 108200002

(51) Int. Cl. H05K 5/03; H05K 5/00; H05K 5/02; H04N 5/225

(52) U.S. Cl. CPC H05K 5/03; H05K 5/0017; H04N 5/2257; H04N 5/2252; H05K 5/0217

(57) ABSTRACT

An electronic device includes a front bezel, a panel module, an image capturing module and a sliding cover assembly. The front bezel is disposed between the panel module and the image capturing module. The image capturing module is for capturing light passing through the panel module and entering an opening on the front bezel to generate an image information. The sliding cover assembly includes a covering component movably disposed between a front side of the front bezel and the panel module. The covering component is moveable relative to the front bezel for selectively covering the opening to prevent the light from entering into the opening so as to prevent the image capturing module from generating the image information or not covering the opening to allow the light to enter into the opening so as to allow the image capturing module to generate the image information.

### BACKGROUND OF THE INVENTION

### 1. Field of the Invention

The present invention relates to an electronic device including an image capturing module, and more particularly, to an electronic device with capability of covering an image capturing module thereof.

### 2. Description of the Prior Art

With advance of technology, an electronic device usually includes an image capturing module to meet different users' needs, such as for videoconference, remote patient monitor, etc. The conventional image capturing module is powered on or powered off by a physical button or a visual icon of software application. However, a camera of the image capturing module still faces a user even if the image capturing module is powered off. It is not easy for the user to figure out whether the image capturing module is powered off correctly or not, which results in privacy concerns.

### SUMMARY OF THE INVENTION

Therefore, it is an objective of the present invention to provide an electronic device with capability of covering an image capturing module thereof for solving the aforementioned problem.

In order to achieve the aforementioned objective, the present invention discloses an electronic device. The electronic device includes a front bezel, a panel module, an image capturing module and a sliding cover assembly. The front bezel includes a front side and a rear side. An opening is formed on the front bezel. The panel module is disposed on the front side of the front bezel. The panel module includes a transparent portion and a display portion. The transparent portion is located at a position corresponding to the opening, and the display portion is configured to display images. The image capturing module is disposed on the rear side of the front bezel and located at a position corresponding to the opening, and the image capturing module is configured to capture light penetrating through the transparent portion and entering the opening so as to generate an image information. The sliding cover assembly includes a covering component movably disposed between the front side of the front bezel and the panel module and switchable between a first position and a second position relative to the front bezel. When the covering component is located at the first position, the covering component covers the opening to prevent the light from entering into the opening, so as to prevent the image capturing module from generating the image information, and when the covering component is located at the second position, the covering component does not cover the opening to allow the light to enter into the opening, so as to allow the image capturing module to generate the image information.

According to an embodiment of the present invention, the sliding cover assembly further includes a driving component movably disposed on the rear side of the front bezel and connected to the covering component, and the driving component is configured to drive the covering component to switch between the first position and the second position relative to the front bezel.

According to an embodiment of the present invention, a through slot is formed on the front bezel. The covering component is formed in an L shape. The covering component includes a covering portion and a connecting portion. The covering portion is located between the front side of the front bezel and the panel module and configured to cover the opening, and the connecting portion slidably passes through the through slot and is connected to the covering portion and the driving component.

According to an embodiment of the present invention, an engaging hole is formed on the connecting portion, the driving component includes an engaging protrusion, and the driving component and the covering component are connected to each other by engagement of the engaging protrusion and the engaging hole.

According to an embodiment of the present invention, a slanted surface is formed on the front side of the front bezel, and the through slot is adjacent to a side of the slanted surface near the rear side of the front bezel.

According to an embodiment of the present invention, at least one sliding slot is formed on the rear side of the front bezel. The driving component includes at least one engaging portion, and the driving component is slidable relative to the front bezel by cooperation of the at least one engaging portion and the at least one sliding slot.

According to an embodiment of the present invention, the electronic device further includes a rear cover disposed on the rear side of the front bezel.

According to an embodiment of the present invention, an exposing slot is formed on the rear cover, and the driving component includes an operating portion exposed out of the exposing slot and slidable within the exposing slot.

According to an embodiment of the present invention, the covering component is made of resilient material.

According to an embodiment of the present invention, the electronic device further includes a rear cover disposed on the rear side of the front bezel.

In summary, the present invention utilizes the covering component for selectively covering the opening to prevent the light from entering into the opening so as to prevent the image capturing module from generating the image information or not covering the opening to allow the light to enter into the opening so as to allow the image capturing module to generate the image information. In such a way, even if the image capturing module is not powered off correctly or someone controls the image capturing module remotely by an application program, the image capturing module is in no way capable of capturing an image of a user. Therefore, the present invention can reduce a risk of privacy leakage and eliminate users' concerns. Furthermore, since the covering component is located between the front bezel and the panel module, a distance between the image capturing module and the panel module and a distance between the image capturing module and the front bezel can be reduced, so that a size of the transparent portion of the panel module and a size of the opening on the front bezel can be reduced without affecting a field of view of the image capturing module. Besides, the operating portion is exposed out of the rear cover of the electronic device, which improves aesthetic appearance of the electronic device. Moreover, the covering component is made of the resilient material, which makes assembly of the covering component easier.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 and FIG. 2 are partial schematic diagrams of an electronic device at different views according to an embodiment of the present invention.

FIG. 3 is a partial exploded diagram of the electronic device according to the embodiment of the present invention.

FIG. 4 is another partial exploded diagram of the electronic device at another view according to the embodiment of the present invention.

FIG. 5 is a diagram of a sliding cover assembly according to the embodiment of the present invention.

FIG. 6 and FIG. 7 are partial diagrams of the electronic device at different views according to the embodiment of the present invention.

FIG. 8 is a diagram of the electronic device in a first state according to the embodiment of the present invention.

FIG. 9 is a diagram of the electronic device in a second state according to the embodiment of the present invention.

### DETAILED DESCRIPTION

In the following detailed description of the preferred embodiments, reference is made to the accompanying drawings which form a part hereof, and in which is shown by way of illustration specific embodiments in which the invention may be practiced. In this regard, directional terminology, such as “top,” “bottom,” “front,” “back,” etc., is used with reference to the orientation of the Figure (s) being described. The components of the present invention can be positioned in a number of different orientations. As such, the directional terminology is used for purposes of illustration and is in no way limiting. Accordingly, the drawings and descriptions will be regarded as illustrative in nature and not as restrictive.

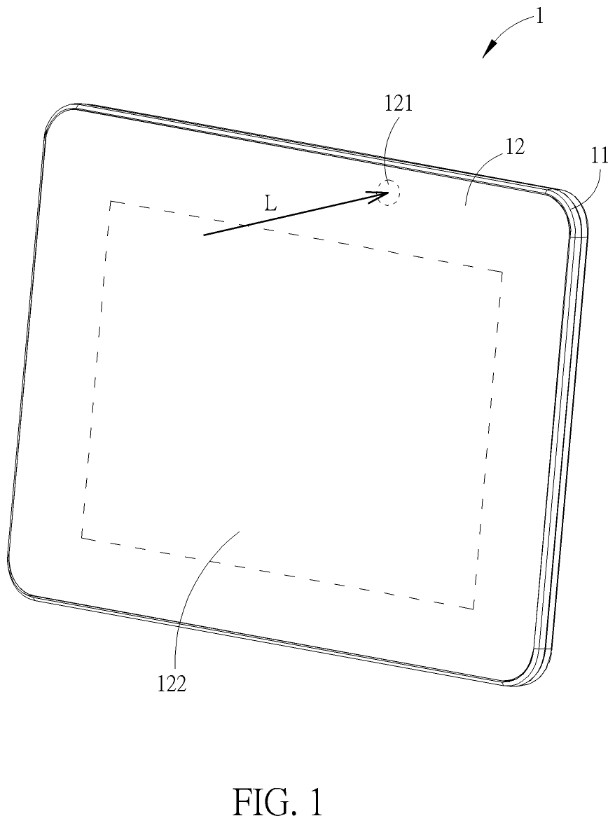

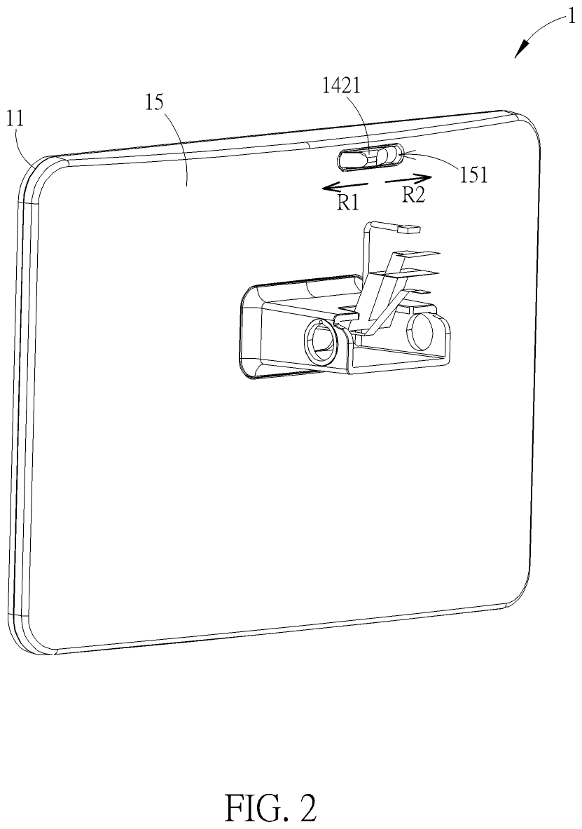

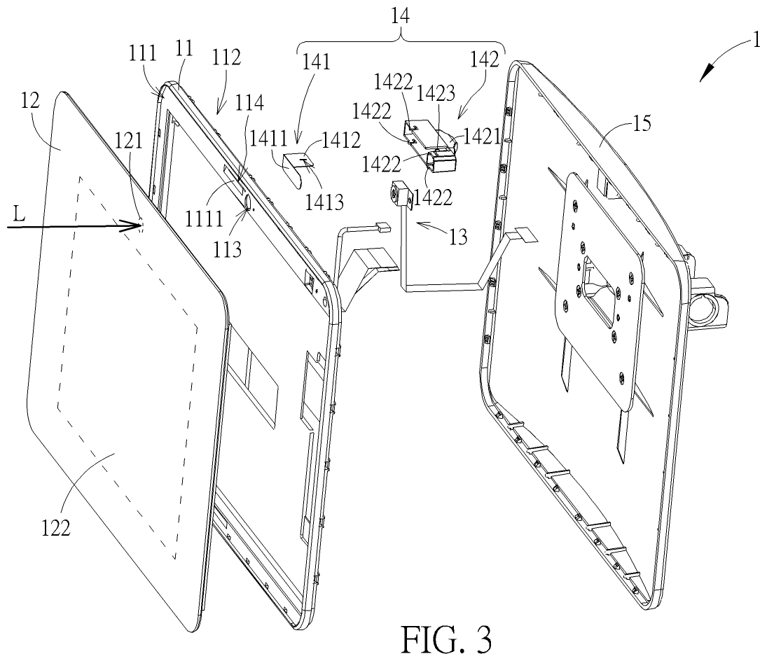

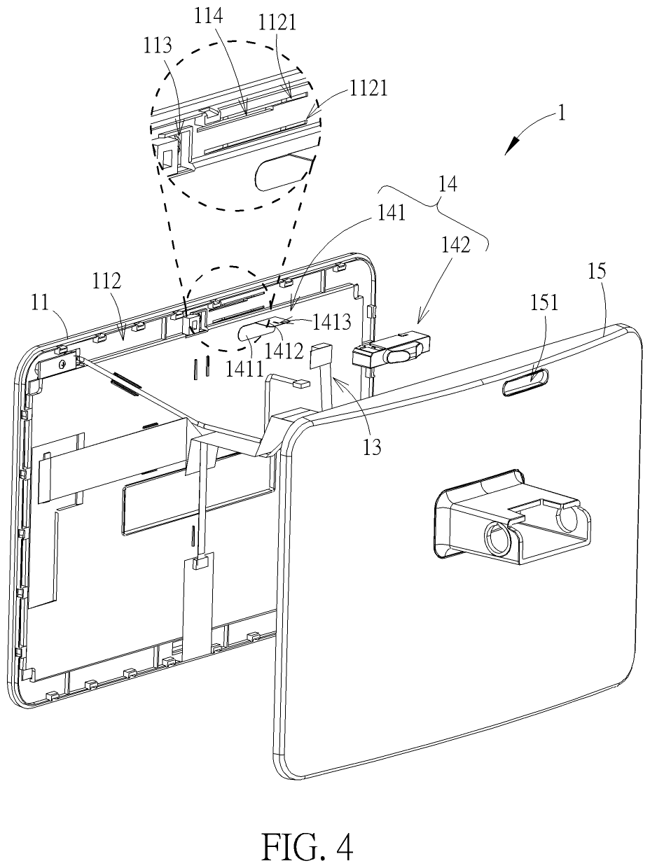

Please refer to FIG. 1 to FIG. 4. FIG. 1 and FIG. 2 are partial schematic diagrams of an electronic device 1 at different views according to an embodiment of the present invention. FIG. 3 is a partial exploded diagram of the electronic device 1 according to the embodiment of the present invention. FIG. 4 is another partial exploded diagram of the electronic device 1 at another view according to the embodiment of the present invention. As shown in FIG. 1 to FIG. 4, the electronic device 1 includes a front bezel 11, a panel module 12, an image capturing device 13, a sliding cover assembly 14, a rear cover 15, and a supporting seat which is not shown in the figures. The front bezel 11 includes a front side 111 and a rear side 112. An opening 113 is formed on the front bezel 11. The panel module 12 is disposed on the front side 111 of the front bezel 11. The panel module 12 includes a transparent portion 121 and a display portion 122. The transparent portion 121 is located at a position corresponding to the opening 113 for allowing environmental light to penetrate through the transparent portion 121 and enter into the opening 113. The display portion 122 is for displaying images. In this embodiment, the display portion 122 can be located at a central portion of the panel module 12, and the transparent portion 121 can be formed on a non-display area located outside a periphery of the display portion 122 and located at a position corresponding to the opening 113. The image capturing module 13 is disposed on the rear side 112 of the front bezel 11 and located a position corresponding to the opening 113. The image capturing module 13 is for capturing a light L penetrating through the transparent portion 121 and entering into the opening 113 so as to generate an image information corresponding to the light L.

The sliding cover assembly 14 is movably disposed on the front bezel 11 for covering the opening 113 to prevent the light L from entering into the opening 113 so as to prevent the image capturing module 13 from generating the image information, or for not covering the opening 113 to allow the light L to enter into the opening 113 so as to allow the image capturing module 13 to generate the image information. The rear cover 15 is disposed on the rear side 112 of the front bezel 11 and for covering the image capturing module 13, the sliding cover assembly 14 and other internal components. The supporting seat is pivoted to the rear cover 15 and for providing support to the electronic device 1 on a supporting surface, such as a desktop, which is not shown in the figures. A user can adjust an angle of the panel module 12 and/or an angle of the image capturing module 13 relative to the user by pivotal movement of the rear cover 15 relative to the supporting seat. In this embodiment, the electronic device 1 can be a videoconference device, the panel module 12 can be a touch display panel, and the image capturing module 13 can be a camera module. However, the present invention is not limited thereto. For example, in another embodiment, the electronic device also can be a laptop computer or a display device, and the panel module also can be a display panel.

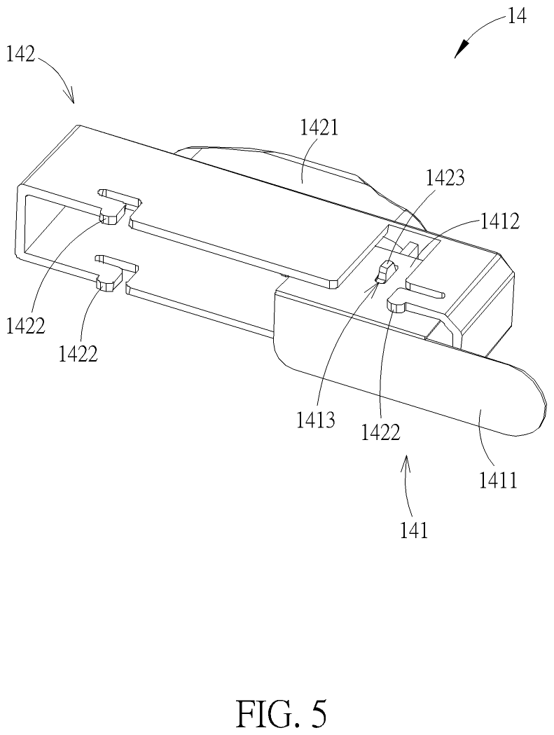

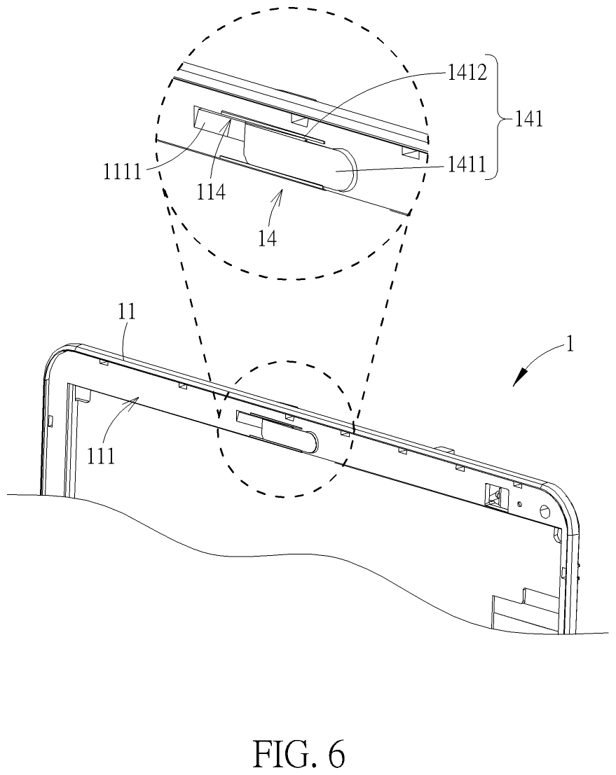

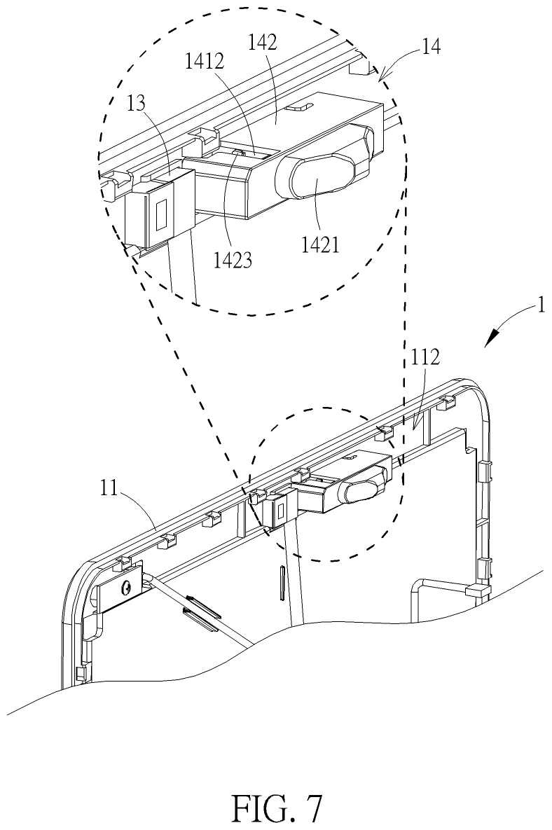

Please refer to FIG. 1 to FIG. 7. FIG. 5 is a diagram of the sliding cover assembly 14 according to the embodiment of the present invention. FIG. 6 and FIG. 7 are partial diagrams of the electronic device 1 at different views according to the embodiment of the present invention. As shown in FIG. 1 to FIG. 7, the sliding cover assembly 14 includes a covering component 141 and a driving component 142. The covering component 141 is movably disposed between the front side 111 of the front bezel 11 and the panel module 12 and movable relative to the front bezel 11. The driving component 142 is movably disposed on the rear side 112 of the front bezel and connected to the covering component 141. The driving component 142 is for driving the covering component 141 to move relative to the front bezel 11. Specifically, a through slot 114 is formed on the front bezel 11. Two sliding slots 1121 are formed on the rear side 112 of the front bezel 11. The covering component 141 is formed in an L shape. The covering component 141 includes a covering portion 1411 and a connecting portion 1412. The covering portion 1411 is located between the front side 111 of the front bezel 11 and the panel module 12 and for covering the opening 113. The covering portion 1411 is made of non-transparent material which can effectively block outside light. The connecting portion 1412 slidably passes through the through slot 114 and is connected to the covering portion 1411 and the driving component 142. An exposing slot 151 is formed on the rear cover 15. The driving component 142 includes an operating portion 1421 and four engaging portions 1422. The operating portion 1421 is exposed out of the exposing slot 151 and slidable within the exposing slot 151 for allowing the user to operate the operating portion 142 to drive the covering portion 1411 to move relative to the front bezel 11. The four engaging portions 1422 are slidably disposed inside the corresponding sliding slots 1121, so that the driving component 142 can slide relative to the front bezel 11 by cooperation of the sliding slots 1121 and the engaging portions 1422. However, the structures of the sliding cover assembly 14, the front bezel 11 and the rear cover 15 are not limited to this embodiment. It depends on practical demands.

In this embodiment, an engaging hole 1413 can be formed on the connecting portion 1412. The driving component 142 can further include an engaging protrusion 1423. The driving component 142 and the covering component 141 can be connected to each other by engagement of the engaging protrusion 1423 and the engaging hole 1413. However, the present invention is not limited to this embodiment. For example, in another embodiment, the driving component and the covering component also can be an integrally formed structure.

It should be noticed that, in order to make assembly of the covering component 141 easier, the covering component 141 can be made of resilient material, such as Mylar. A slanted surface 1111 can be formed on the front side 111 of the front bezel 11. The through slot 114 can be adjacent to a side of the slanted surface 1111 near the rear side 112 of the front bezel 11. For assembling the covering component 141, the covering portion 1411 can be operated to pass through the through slot 114 and then move along the slanted surface 1111 until the connecting portion 1412 is located within the through slot 114, which completes the assembly of the covering component 141. Furthermore, if there is an interference during the assembly, e.g., if the covering component 141 is blocked by another internal component, the covering component 141 can be bent to avoid the interference.

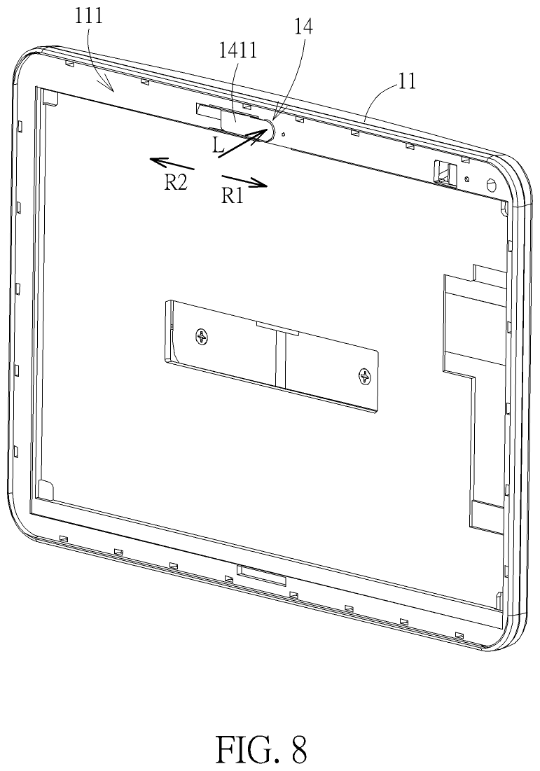

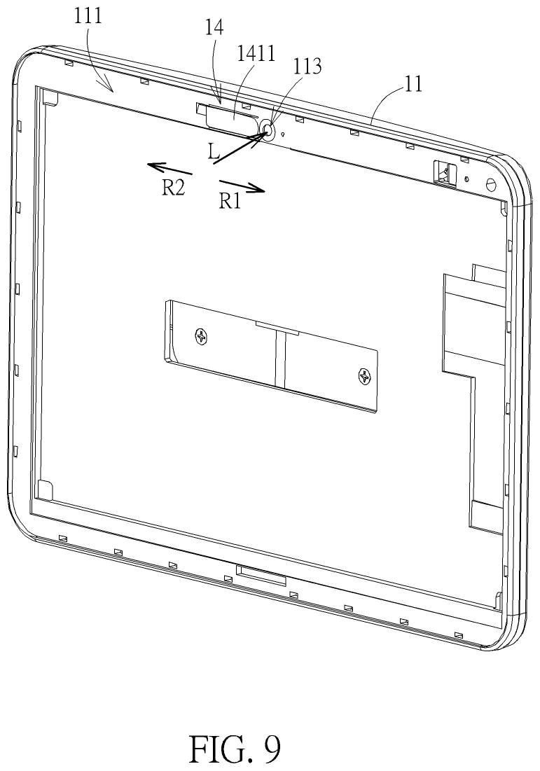

Operational principle of the electronic device 1 is introduced as follows. Please refer to FIG. 1, FIG. 2, FIG. 8 and FIG. 9. FIG. 8 is a diagram of the electronic device 1 in a first state according to the embodiment of the present invention. FIG. 9 is a diagram of the electronic device 1 in a second state according to the embodiment of the present invention. When it is desired to prevent the image capturing module 13 from generating the image information, the operating portion 1421 can be operated to slide relative to the exposing slot 151 along a first direction R1 for driving the covering component 141 to slide relative to the front bezel 11 along the first direction R1 to a first position as shown in FIG. 8. When the covering component 141 is located at the first position, the covering component 141 covers the opening 113, so that the light L is prevented from entering into the opening 113 by the covering component 141. Therefore, the image capturing module 13 cannot generate the image information. On the other hand, when it is desired to allow the image capturing module to generate the image information, the operating portion 1421 can be operated to slide relative to the exposing slot 151 along a second direction R2 opposite to the first direction R1 for driving the covering component 141 to slide along the second direction R2 from the first position as shown in FIG. 8 to a second position as shown in FIG. 9. When the covering component 141 is located at the second position, the covering component 141 does not cover the opening 113, so that the light L is allowed to enter into the opening 113. Therefore, the image capturing module 13 can generate the image information.

In contrast to the prior art, the present invention utilizes the covering component for selectively covering the opening to prevent the light from entering into the opening so as to prevent the image capturing module from generating the image information or not covering the opening to allow the light to enter into the opening so as to allow the image capturing module to generate the image information. In such a way, even if the image capturing module is not powered off correctly or someone controls the image capturing module remotely by an application program, the image capturing module is in no way capable of capturing an image of a user. Therefore, the present invention can reduce a risk of privacy leakage and eliminate users' concerns. Furthermore, since the covering component is located between the front bezel and the panel module, a distance between the image capturing module and the panel module and a distance between the image capturing module and the front bezel can be reduced, so that a size of the transparent portion of the panel module and a size of the opening on the front bezel can be reduced without affecting a field of view of the image capturing module. Besides, the operating portion is exposed out of the rear cover of the electronic device, which improves aesthetic appearance of the electronic device. Moreover, the covering component is made of the resilient material, which makes assembly of the covering component easier.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electronic device comprising:
a front bezel comprising a front side and a rear side, an opening being formed on the front bezel;
a panel module disposed on the front side of the front bezel, the panel module comprising a transparent portion and a display portion, the transparent portion being located at a position corresponding to the opening, and the display portion being configured to display images;
an image capturing module disposed on the rear side of the front bezel and located at a position corresponding to the opening, and the image capturing module being configured to capture light penetrating through the transparent portion and entering the opening so as to generate an image information; and
a sliding cover assembly comprising a covering component movably disposed between the front side of the front bezel and the panel module and switchable between a first position and a second position relative to the front bezel, when the covering component is located at the first position, the covering component covering the opening to prevent the light from entering into the opening, so as to prevent the image capturing module from generating the image information, and when the covering component is located at the second position, the covering component not covering the opening to allow the light to enter into the opening, so as to allow the image capturing module to generate the image information.

2. The electronic device of claim 1, wherein the sliding cover assembly further comprises a driving component movably disposed on the rear side of the front bezel and connected to the covering component, and the driving component is configured to drive the covering component to switch between the first position and the second position relative to the front bezel.

3. The electronic device of claim 2, wherein at least one sliding slot is formed on the rear side of the front bezel, the driving component comprises at least one engaging portion, and the driving component is slidable relative to the front bezel by cooperation of the at least one engaging portion and the at least one sliding slot.

4. The electronic device of claim 2, further comprising a rear cover disposed on the rear side of the front bezel.

5. The electronic device of claim 4, wherein an exposing slot is formed on the rear cover, and the driving component comprises an operating portion exposed out of the exposing slot and slidable within the exposing slot.

6. The electronic device of claim 2, wherein a through slot is formed on the front bezel, the covering component is formed in an L shape, the covering component comprises a covering portion and a connecting portion, the covering portion is located between the front side of the front bezel and the panel module and configured to cover the opening, and the connecting portion slidably passes through the through slot and is connected to the covering portion and the driving component.

7. The electronic device of claim 6, wherein at least one sliding slot is formed on the rear side of the front bezel, the driving component comprises at least one engaging portion, and the driving component is slidable relative to the front bezel by cooperation of the at least one engaging portion and the at least one sliding slot.

8. The electronic device of claim 6, further comprising a rear cover disposed on the rear side of the front bezel.

9. The electronic device of claim 8, wherein an exposing slot is formed on the rear cover, and the driving component comprises an operating portion exposed out of the exposing slot and slidable within the exposing slot.

10. The electronic device of claim 6, wherein an engaging hole is formed on the connecting portion, the driving component comprises an engaging protrusion, and the driving component and the covering component are connected to each other by engagement of the engaging protrusion and the engaging hole.

11. The electronic device of claim 10, wherein at least one sliding slot is formed on the rear side of the front bezel, the driving component comprises at least one engaging portion, and the driving component is slidable relative to the front bezel by cooperation of the at least one engaging portion and the at least one sliding slot.

12. The electronic device of claim 10, further comprising a rear cover disposed on the rear side of the front bezel.

13. The electronic device of claim 12, wherein an exposing slot is formed on the rear cover, and the driving component comprises an operating portion exposed out of the exposing slot and slidable within the exposing slot.

14. The electronic device of claim 6, wherein a slanted surface is formed on the front side of the front bezel, and the through slot is adjacent to a side of the slanted surface near the rear side of the front bezel.

15. The electronic device of claim 14, wherein at least one sliding slot is formed on the rear side of the front bezel, the driving component comprises at least one engaging portion, and the driving component is slidable relative to the front bezel by cooperation of the at least one engaging portion and the at least one sliding slot.

16. The electronic device of claim 14, further comprising a rear cover disposed on the rear side of the front bezel.

17. The electronic device of claim 16, wherein an exposing slot is formed on the rear cover, and the driving component comprises an operating portion exposed out of the exposing slot and slidable within the exposing slot.

18. The electronic device of claim 1, wherein the covering component is made of resilient material.

19. The electronic device of claim 1, further comprising a rear cover disposed on the rear side of the front bezel.
